(19) United States
(12) Patent Application Publication
(10) Pub. No.: US 2026/0277737 A1
(43) Pub. Date: Sep. 17, 2026

(54) MEMORY APPARATUS, IMAGE SENSOR, AND ELECTRONIC APPARATUS

(71) Applicant: SONY SEMICONDUCTOR SOLUTIONS CORPORATION, KANAGAWA (JP)

(72) Inventor: YASUO KANDA, KANAGAWA (JP)

(21) Appl. No.: 19/163,436

(22) PCT Filed: Mar. 11, 2024
(86) PCT No.: PCT/JP2024/009305

§ 371 Date: Sep. 9, 2025

(30) Foreign Application Priority Data
Mar. 30, 2023 (JP) 2023-056601

(51) Int. Cl. G06F 11/10

(52) U.S. Cl. CPC G06F 11/1004

(57) ABSTRACT

An increase in the size of a memory apparatus that stores image data or the like is reduced. A memory apparatus according to the present disclosure includes a first memory and a second memory. The first memory included in the memory apparatus according to the present disclosure includes an SRAM and holds data of the high-order bits of image data. The second memory included in the memory apparatus according to the present disclosure includes a memory having a cell area smaller than a cell area of the SRAM of the first memory according to the present disclosure, and the second memory holds data of the low-order bits of the image data.

### FIELD

The present disclosure relates to a memory apparatus, an image sensor, and an electronic apparatus.

### BACKGROUND

An electronic apparatus including a memory apparatus using a semiconductor memory such as static random access memory (SRAM) has been proposed (see, for example, Patent Literature 1). A memory that stores information on a defective pixel of an imaging element is used in the electronic apparatus (imaging apparatus) of the prior art.

### CITATION LIST

### Patent Literature

Patent Literature 1: JP 2013-093685 A

### SUMMARY

### Technical Problem

The SRAM has a feature that an error occurrence rate of held data is low, and is used for a memory apparatus that stores data having high reliability. However, since the SRAM has a larger cell area than that of a DRAM or the like, there is a problem that the size of the memory apparatus increases.

Therefore, the present disclosure proposes a memory apparatus that reduces an increase in size, an image sensor using the memory apparatus, and an electronic apparatus.

### Solution to Problem

A memory apparatus according to the present disclosure includes a first memory and a second memory. The first memory includes an SRAM and holds data of a high-order bit of image data. The second memory includes a memory having a cell area smaller than a cell area of the SRAM and holds data of a low-order bit of the image data.

### BRIEF DESCRIPTION OF DRAWINGS

FIG. 1 is a diagram illustrating a configuration example of a memory apparatus according to a first embodiment of the present disclosure.

FIG. 2 is a diagram illustrating another configuration example of the memory apparatus according to the first embodiment of the present disclosure.

FIG. 3 is a diagram illustrating a configuration example of a memory apparatus according to a second embodiment of the present disclosure.

FIG. 4 is a diagram illustrating another configuration example of the memory apparatus according to the second embodiment of the present disclosure.

FIG. 5 is a diagram illustrating a configuration example of an electronic apparatus to which technology according to an embodiment of the present disclosure can be applied.

FIG. 6 is a diagram illustrating a configuration example of an image sensor to which the technology according to the embodiment of the present disclosure can be applied.

FIG. 7 is a diagram illustrating an example of image data generation in the image sensor to which the technology according to the embodiment of the present disclosure can be applied.

### DESCRIPTION OF EMBODIMENTS

Hereinafter, embodiments of the present disclosure will be described in detail on the basis of the drawings. The description will be given in the following order. Note that in the respective embodiments below, the same parts are denoted by the same reference signs, and redundant description will be omitted.
1. First Embodiment
2. Second Embodiment
3. Application to Electronic Apparatus

### 1. First Embodiment

### [Configuration of Memory Apparatus]

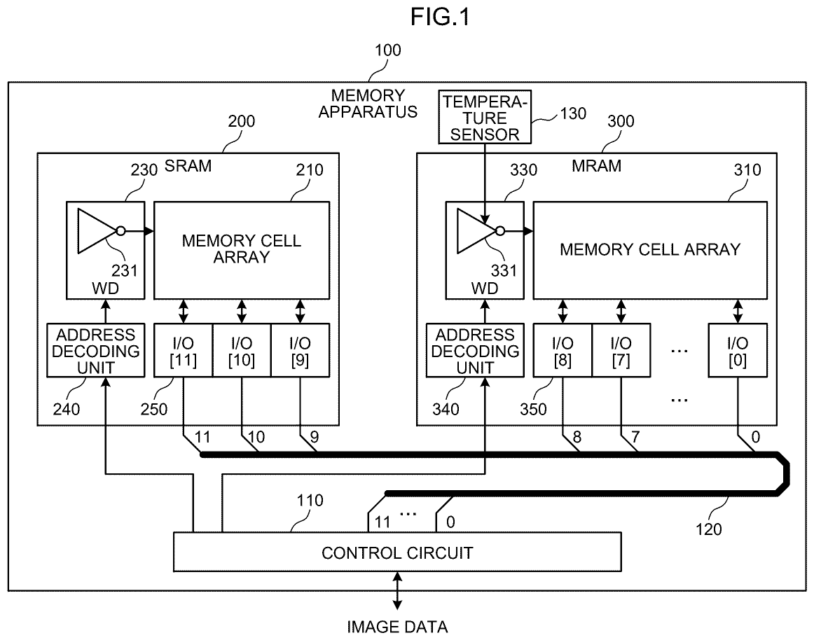

FIG. 1 is a diagram illustrating a configuration example of a memory apparatus according to a first embodiment of the present disclosure. The figure is a block diagram illustrating a configuration example of a memory apparatus 100. The memory apparatus 100 is assumed to be a frame memory that holds image data. In addition, the image data is assumed to be data with a 12-bit width. Here, a bit [11] corresponds to a most significant bit (MSB), and a bit [0] corresponds to a least significant bit (LSB). The memory apparatus 100 includes an SRAM 200, an MRAM 300, a temperature sensor 130, and a control circuit 110.

The SRAM 200 is a memory that includes an SRAM and holds data of high-order bits of the image data. The SRAM 200 in FIG. 1 illustrates an example of a case where data of the high-order three bits of the image data is held. The SRAM 200 includes a memory cell array 210, a word line driving unit (described as WD in FIG. 1) 230, an address decoding unit 240, and a data I/O buffer (described as I/O in FIG. 1) 250. Note that the SRAM 200 is an example of a “first memory” of the present disclosure.

The memory cell array 210 is configured by arranging memory cells, which are unit elements that store data, in a two-dimensional matrix. Word lines and bit lines are wired to the memory cells of the memory cell array 210.

The address decoding unit 240 selects a word line of the memory cell array 210 on the basis of an address signal from the control circuit 110.

The word line driving unit 230 drives the word line selected by the address decoding unit 240. The word line driving unit 230 includes a plurality of driving units 231 that drives the word lines. Among the plurality of driving units 231, a driving unit 231 connected to the word line selected by the address decoding unit 240 outputs a driving voltage.

A data I/O buffer 250 is a bidirectional buffer that exchanges data with the bit line. [11] to [0] of the data I/O buffer 250 in FIG. 1 represent bits of data. As described above, the SRAM 200 holds the data of the high-order three bits of the 12-bit image data. In other words, the SRAM 200 holds data of bits [11] to [9]. The data I/O buffer 250 is connected to a bus 120.

The MRAM 300 is a memory that includes a magnetoresistive RAM (MRAM) that is a magnetoresistive effect memory and holds data of low-order bits of image data. The MRAM 300 in FIG. 1 illustrates an example of a case where data of the low-order nine bits of the image data is held. The MRAM 300 includes a memory cell array 310, a word line driving unit 330, an address decoding unit 340, and a data I/O buffer 350. Note that the MRAM 300 is an example of a “second memory” of the present disclosure.

Similarly to the memory cell array 210, the memory cell array 310 is configured by arranging memory cells, which are unit elements that store data, in a two-dimensional matrix.

Similarly to the address decoding unit 240, the address decoding unit 340 selects a word line of the memory cell array 310 on the basis of an address signal from the control circuit 110.

Similarly to the word line driving unit 230, the word line driving unit 330 drives the word line selected by the address decoding unit 340. The word line driving unit 330 includes a plurality of driving units 331 that drives word lines. Among the plurality of driving units 331, a driving unit 331 connected to the word line selected by the address decoding unit 340 outputs a driving voltage. Note that the driving unit 331 adjusts the driving voltage on the basis of a signal from the temperature sensor 130.

Similarly to the data I/O buffer 250, the data I/O buffer 350 is a bidirectional buffer that exchanges data with a bit line. As described above, the MRAM 300 holds the data of the lower-order nine bits of the 12-bit image data. In other words, the MRAM 300 holds data of bits [8] to [0]. The data I/O buffer 350 is connected to a bus 120.

The control circuit 110 controls the entire memory apparatus 100. The control circuit 110 outputs an address signal to the address decoding unit 240 of the SRAM 200 and the address decoding unit 340 of the MRAM 300. In addition, the control circuit 110 inputs and outputs the image data between the data I/O buffer 250 of the SRAM 200 and the data I/O buffer 350 of the MRAM 300 via the bus 120. At this time, the control circuit 110 performs control to allocate the data of the high-order three bits of the image data to the SRAM 200, and performs control to allocate the data of the low-order nine bits of the image data to the MRAM 300.

The temperature sensor 130 measures a temperature and outputs a signal corresponding to a measurement result to the driving unit 331 of the MRAM 300.

The SRAM has a larger cell area than that of the MRAM. Specifically, the ratio of the cell area of the SRAM to the cell area of the MRAM is 9 to 3. Therefore, in a case where the memory apparatus 100 adopts a configuration in which all the 12-bit image data is held in the SRAM, a chip size increases. Meanwhile, both the SRAM and the MRAM are arranged in the memory apparatus 100 and the image data is distributed, whereby an increase in the chip size can be reduced. For example, the memory apparatus 100 is assumed to have a configuration in which data corresponding to two bits of the image data is distributed to the SRAM, and data corresponding to the remaining 10 bits is distributed to the MRAM. In this case, the chip size of the memory apparatus 100 can be reduced to ½ as compared with a case where all the image data is held in the SRAM.

Meanwhile, the MRAM has a higher error occurrence rate of the held data than that of the SRAM. Therefore, it is possible to reduce the influence of the error occurrence rate by allocating the image data of high-order bits requiring high reliability to the SRAM and allocating the image data of low-order bits to the MRAM.

In consideration of the cell area and the error occurrence rate described above, it is possible to adopt a configuration in which data of at least high-order two bits of the image data is held in the SRAM 200 and a configuration in which data of the remaining 10 bits of the image data are held in the MRAM 300. As a result, it is possible to reduce an increase in the chip size of the memory apparatus 100 while reducing the influence of the error occurrence rate of the image data. FIG. 1 describes an example in which data of the high-order three bits are held in the SRAM 200.

### [Another Configuration of Memory Apparatus]

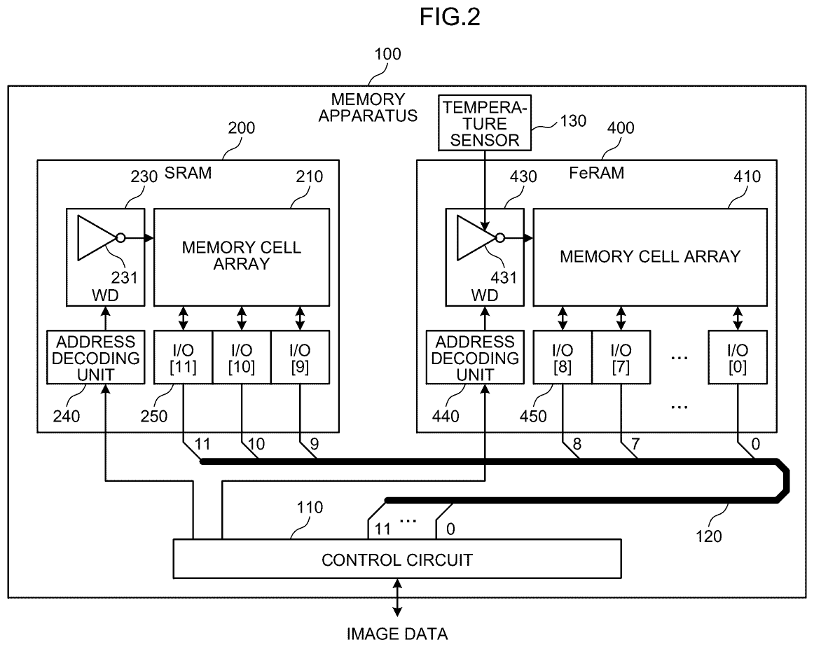

FIG. 2 is a diagram illustrating another configuration example of the memory apparatus according to the first embodiment of the present disclosure. The figure is a block diagram illustrating a configuration example of a memory apparatus 100 similarly to FIG. 1. The memory apparatus 100 in the figure is different from the memory apparatus 100 in FIG. 1 in that the memory apparatus 100 in the figure includes a FeRAM 400 instead of the MRAM 300.

The FeRAM 400 is a memory that includes a ferroelectric RAM (FeRAM) that is a ferroelectric memory and holds data of the lower-order bits of image data. The FeRAM 400 in FIG. 2 illustrates an example in a case where data of the low-order nine bits of the image data is held. The FeRAM 400 includes a memory cell array 410, a word line driving unit 430, an address decoding unit 440, and a data I/O buffer 450. Note that the FeRAM 400 is an example of the “second memory” of the present disclosure.

Similarly to the memory cell array 310, the memory cell array 410 is configured by arranging memory cells, which are unit elements that store data, in a two-dimensional matrix.

Similarly to the address decoding unit 340, the address decoding unit 440 selects a word line of the memory cell array 410 on the basis of an address signal from a control circuit 110.

Similarly to the word line driving unit 330, the word line driving unit 430 drives the word line selected by the address decoding unit 440. The word line driving unit 430 includes a plurality of driving units 431 that drives word lines. The driving unit 431 adjusts a driving voltage on the basis of a signal from a temperature sensor 130.

Similarly to the data I/O buffer 350, the data I/O buffer 450 is a bidirectional buffer that exchanges data with a bit line. As described above, the FeRAM 400 holds data of the lower nine bits of the 12-bit image data. In other words, the FeRAM 400 holds data of bits [8] to [0]. The data I/O buffer 450 is connected to a bus 120.

As described above, the memory apparatus 100 according to the first embodiment of the present disclosure causes the SRAM 200 to hold data of the high-order bits of the image data and causes the MRAM 300 or the FeRAM 400 to hold the low-order bits of the image data. As a result, it is possible to reduce an increase in the size of the memory apparatus 100 while reducing the influence of an error occurrence rate of the image data.

### 2. Second Embodiment

The memory apparatus 100 of the first embodiment described above distributes the image data to the SRAM 200 and the MRAM 300 and causes the SRAM 200 and the MRAM 300 to hold the image data. Meanwhile, a memory apparatus 100 according to a second embodiment of the present disclosure is different from that of the first embodiment described above in that data for error correction processing is further held together with image data in an SRAM 200 and an MRAM 300.

### [Configuration of Memory Apparatus]

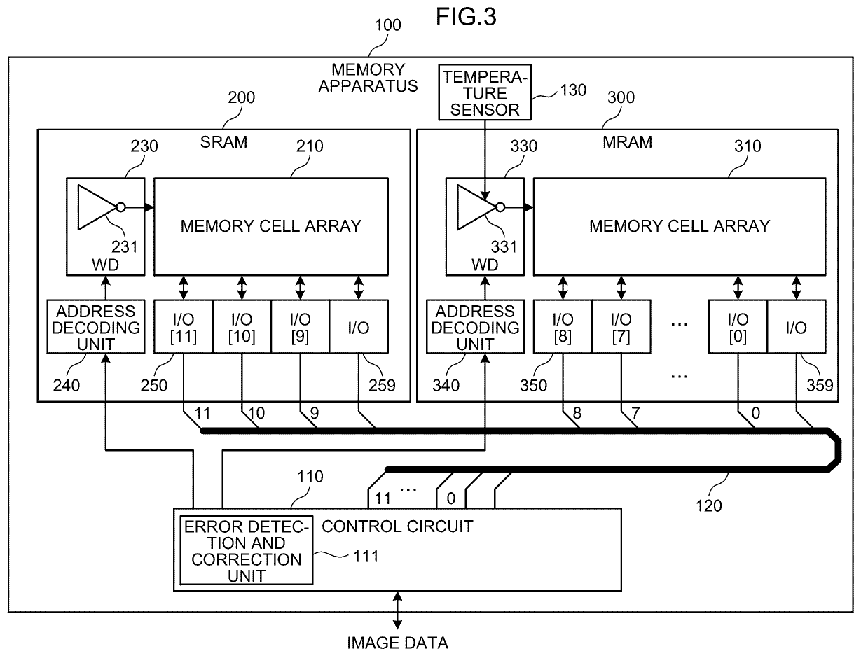

FIG. 3 is a diagram illustrating a configuration example of the memory apparatus according to the second embodiment of the present disclosure. The figure is a block diagram illustrating a configuration example of a memory apparatus 100 similarly to FIG. 1. The memory apparatus 100 in the figure is different from the memory apparatus 100 in FIG. 1 in that the memory apparatus 100 in the figure performs error detection and correction processing of image data.

A control circuit 110 in FIG. 3 includes an error detection and correction unit 111. The error detection and correction unit 111 performs error detection and correction code (ECC) conversion and decoding of the image data. The error detection and correction unit 111 generates redundant data that is data obtained by performing the error detection and correction code conversion on the image data. The control circuit 110 outputs the redundant data to the SRAM 200 and the MRAM 300 together with the image data.

The memory cell array 210 of the SRAM 200 in FIG. 3 includes a redundant area that holds the redundant data. In addition, the SRAM 200 in FIG. 3 further includes a data I/O buffer 259. The data I/O buffer 259 inputs and outputs the redundant data.

A memory cell array 310 of the MRAM 300 in FIG. 3 includes a redundant area that holds the redundant data. In addition, the MRAM 300 in FIG. 3 further includes a data I/O buffer 359. The data I/O buffer 359 inputs and outputs the redundant data.

As described above, the memory apparatus 100 in FIG. 3 is capable of reducing errors in the image data. Note that the memory apparatus 100 can be configured to have an I/O redundancy function instead of the error detection and correction processing of the image data. In this case, an I/O redundancy control unit is arranged in the control circuit 110, and the data I/O buffer 259 of the memory cell array 210 and the data I/O buffer 359 of the memory cell array 310 are used for I/O redundancy.

### [Another Configuration of Memory Apparatus]

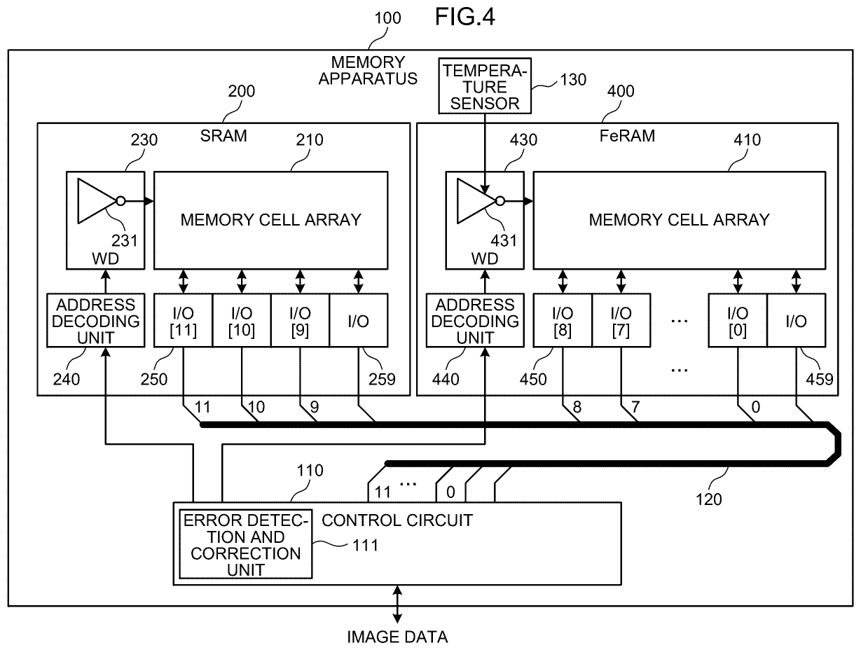

FIG. 4 is a diagram illustrating another configuration example of the memory apparatus according to the second embodiment of the present disclosure. The figure is a block diagram illustrating a configuration example of the memory apparatus 100 similarly to FIG. 3. The memory apparatus 100 in the figure is different from the memory apparatus 100 in FIG. 3 in that the memory apparatus 100 in the figure includes a FeRAM 400 instead of the MRAM 300. A memory cell array 410 of a FeRAM 400 includes a redundant area that holds redundant data. In addition, the FeRAM 400 in the figure includes a data I/O buffer 459 corresponding to redundant data.

Configurations of the memory apparatus 100 other than the above configuration are similar to those of the memory apparatus 100 in the first embodiment of the present disclosure, and thus the description thereof will be omitted.

As described above, the memory apparatus 100 according to the second embodiment of the present disclosure is capable of reducing the influence of errors in the image data by performing the error detection and correction of the image data.

### 3. Application to Electronic Apparatus

The memory apparatus 100 described above can be applied to various products. An electronic apparatus using the memory apparatus 100 will be described.

### [Configuration of Electronic Apparatus]

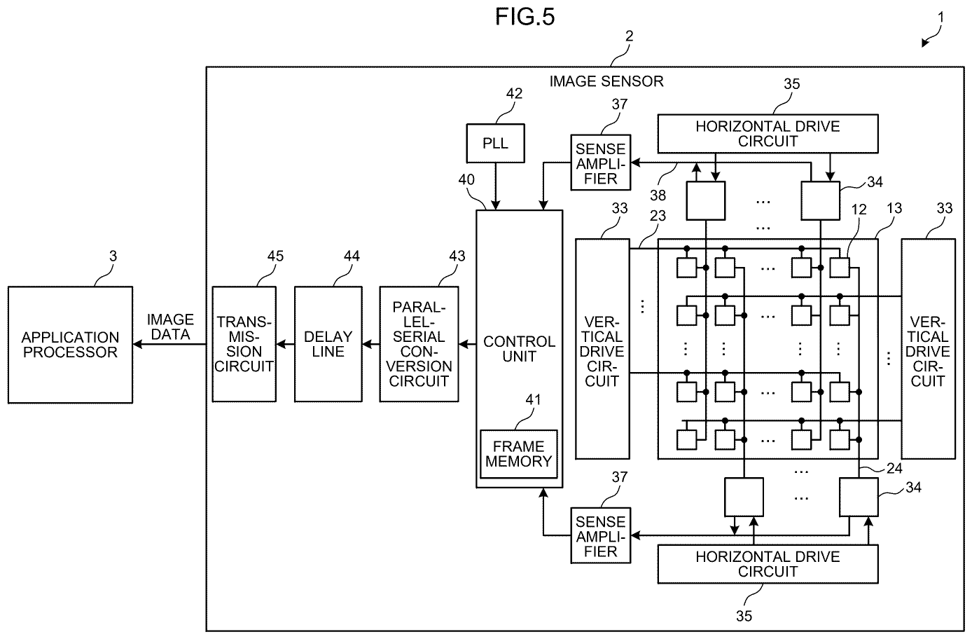

FIG. 5 is a diagram illustrating a configuration example of an electronic apparatus to which technology according to an embodiment of the present disclosure can be applied. The figure is a block diagram illustrating a configuration example of an electronic apparatus 1. The electronic apparatus 1 is an apparatus that generates an image of a subject. The electronic apparatus 1 includes an image sensor 2 and an application processor 3. The image sensor 2 images the subject to generate image data. In addition, the application processor 3 processes the image data.

The image sensor 2 includes a pixel array unit 13 in which pixels 12 including a plurality of photoelectric conversion units are regularly and two-dimensionally arranged on a semiconductor substrate, for example, a silicon substrate, and a peripheral circuit unit. The pixel 12 includes, for example, a photodiode serving as a photoelectric conversion unit and a plurality of pixel transistors (so-called MOS transistors). The plurality of pixel transistors can include, for example, three transistors that are a transfer transistor, a reset transistor, and an amplification transistor. In addition, a selection transistor may be added to constitute four transistors.

The peripheral circuit unit includes a vertical drive circuit 33, an analog-to-digital conversion unit 34, a horizontal drive circuit 35, a sense amplifier 37, a PLL 42, a control unit 40, a parallel-serial conversion circuit 43, a delay line 44, and a transmission circuit 45.

The vertical drive circuit 33 includes, for example, a shift register, selects a pixel drive line 23, supplies a pulse for driving the pixels 12 to the selected pixel drive line 23, and drives a pixel 12 in units of rows. In other words, the vertical drive circuit 33 sequentially selects and scans each pixel 12 of the pixel array unit 13 in units of rows in a vertical direction, and supplies a pixel signal based on a signal charge generated according to the amount of received light in, for example, a photodiode serving as a photoelectric conversion unit of each pixel 12 to the analog-to-digital conversion unit 34 through a vertical signal line 24.

The analog-to-digital conversion unit 34 is arranged, for example, for each column of the pixels 12, and performs analog-to-digital conversion of the pixel signal output from the pixels 12 of one row and transmitted by the vertical signal line 24 to generate an image signal.

The horizontal drive circuit 35 includes, for example, a shift register, sequentially selects each of the analog-to-digital conversion units 34 by sequentially outputting horizontal scanning pulses, and causes each of the analog-to-digital conversion units 34 to output an image signal to a horizontal signal line 38.

The sense amplifier 37 performs signal processing on the image signal sequentially supplied from each of the analog-to-digital conversion units 34 through the horizontal signal line 38, and outputs the processed image signal.

The PLL 42 generates a clock signal and supplies the clock signal to the control unit 40.

The control unit 40 controls the entire image sensor 2. In addition, the control unit 40 processes the image signal output from the sense amplifier 37. At this time, the control unit 40 causes a frame memory 41 included in the control unit 40 to temporarily hold the image signal. The control unit 40 performs processing such as rearrangement of the image signal held in the frame memory 41 to generate image data. The control unit 40 reads out the generated image data from the frame memory 41 and outputs the image data to the parallel-serial conversion circuit 43.

The parallel-serial conversion circuit 43 performs parallel-serial conversion of the image data from the control unit 40. The converted image data is transmitted to the transmission circuit 45 via the delay line 44.

The transmission circuit 45 transmits the image data to the application processor 3. For example, a transmission circuit compatible with low voltage differential signaling (LVDS) can be applied to the transmission circuit 45.

The memory apparatus 100 in FIG. 1 can be applied to the frame memory 41 of the electronic apparatus 1 described above.

### [Configuration of Image Sensor]

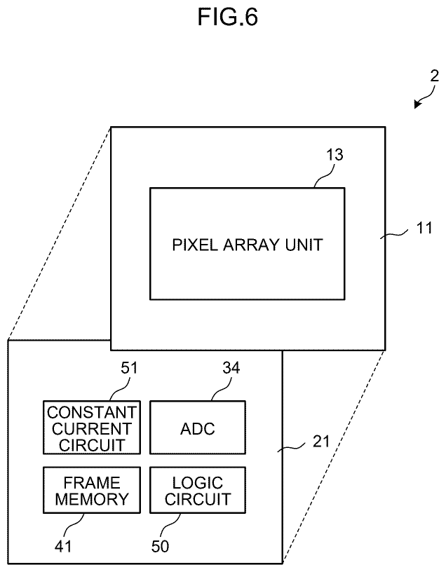

FIG. 6 is a diagram illustrating a configuration example of an image sensor to which the technology according to the embodiment of the present disclosure can be applied. The figure is a diagram illustrating a configuration example of the image sensor 2. The image sensor 2 in the figure illustrates an example in which a first semiconductor substrate 11 on which a pixel array unit 13 is arranged and a second semiconductor substrate 21 on which a peripheral circuit unit is arranged are stacked. On the second semiconductor substrate 21, a constant current circuit 51 (not illustrated in FIG. 5) of the peripheral circuit unit, an analog-to-digital conversion unit (described as ADC in FIG. 6) 34, a frame memory 41, and a logic circuit 50 are arranged. Note that the constant current circuit 51 is a circuit that constitutes a load of a selection transistor of a pixel 12. The constant current circuit 51 is arranged for each vertical signal line 24. In addition, a logic circuit 50 includes another peripheral circuit unit and the like.

Note that the configuration of the image sensor 2 is not limited to this example. For example, the pixel array unit 13, the constant current circuit 51, the analog-to-digital conversion unit 34, the frame memory 41, and the logic circuit 50 can be arranged on one semiconductor substrate.

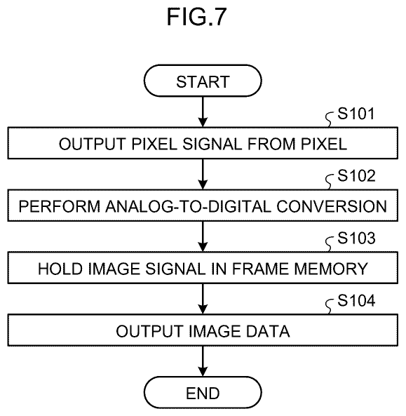

FIG. 7 is a diagram illustrating an example of image data generation in the image sensor to which the technology according to the embodiment of the present disclosure can be applied. The figure is a flowchart illustrating an example of image data generation processing in the image sensor 2. First, the pixel signal is output from the pixel 12 (step S101). Next, the analog-to-digital conversion unit 34 performs analog-to-digital conversion of the pixel signal (step S102). Next, the control unit 40 causes the frame memory 41 to hold the image signal (step S103). Next, the control unit 40 reads out the image data from the frame memory 41 and outputs the image data (step S104). Through the above processing, the image data can be supplied to an external device, for example, the application

Although the embodiments of the present disclosure have been described above, the technical scope of the present disclosure is not limited to the above-described embodiments as they are, and various modifications can be made without departing from the gist of the present disclosure. In addition, components of different embodiments and modification examples may be appropriately combined.

In addition, the processing described using the flowchart and the sequence diagrams in the present specification may not necessarily be performed in the illustrated order. Some processing steps may be performed in parallel. In addition, additional processing steps may be employed, and some processing steps may be omitted.

Note that the effects described in the present specification are merely examples and are not limited, and other effects may be provided.

Note that the present technology can also have the following configurations.
(1)

A memory apparatus comprising:
a first memory that includes an SRAM and holds data of a high-order bit of image data; and
a second memory that includes a memory having a cell area smaller than a cell area of the SRAM, the second memory holding data of a low-order bit of the image data.
(2)

The memory apparatus according to the above (1), wherein the second memory includes a magnetoresistive effect memory as a memory having a cell area smaller than a cell area of the SRAM.
(3)

The memory apparatus according to the above (1), wherein the second memory includes a ferroelectric memory as a memory having a cell area smaller than the cell area of the SRAM.
(4)

The memory apparatus according to any one of the above (1) to (3), wherein the first memory holds data of at least high-order two bits of the image data.
(5)

The memory apparatus according to any one of the above (1) to (4), further comprising an error detection and correction unit that performs error detection and correction processing on the image data held in the second memory. (6)

The memory apparatus according to the above (5), wherein the error detection and correction unit further performs error detection and generation processing on the image data held in the first memory.
(7)

An image sensor comprising:
an imaging element that generates image data;
a first memory that includes an SRAM and holds data of a high-order bit of the image data; and
a second memory that includes a memory having a cell area smaller than a cell area of the SRAM, the second memory holding data of a low-order bit of the image data.
(8)

The image sensor according to the above (7), further comprising:
a first semiconductor substrate on which an imaging element that generates the image data is arranged; and
a second semiconductor substrate on which the first memory and the second memory are arranged, the second semiconductor substrate being stacked on the first semiconductor substrate.

The image sensor according to the above (7), further comprising a semiconductor substrate on which the imaging element that generates the image data, the first memory, and the second memory are arranged.
(10)

An electronic apparatus comprising:
a memory apparatus including
a first memory that includes an SRAM and holds data of a high-order bit of image data, and
a second memory that includes a memory having a cell area smaller than a cell area of the SRAM, the second memory holding data of a low-order bit of the image data; and
a processing unit that performs processing of the image data.

### REFERENCE SIGNS LIST

1 ELECTRONIC APPARATUS
2 IMAGE SENSOR
3 APPLICATION PROCESSOR
11 FIRST SEMICONDUCTOR SUBSTRATE
12 PIXEL
21 SECOND SEMICONDUCTOR SUBSTRATE
41 FRAME MEMORY
100 MEMORY APPARATUS
111 ERROR DETECTION AND CORRECTION UNIT
200 SRAM
300 MRAM
400 FeRAM

1. A memory apparatus comprising:
a first memory that includes an SRAM and holds data of a high-order bit of image data; and
a second memory that includes a memory having a cell area smaller than a cell area of the SRAM, the second memory holding data of a low-order bit of the image data.

2. The memory apparatus according to claim 1, wherein the second memory includes a magnetoresistive effect memory as a memory having a cell area smaller than a cell area of the SRAM.

3. The memory apparatus according to claim 1, wherein the second memory includes a ferroelectric memory as a memory having a cell area smaller than the cell area of the SRAM.

4. The memory apparatus according to claim 1, wherein the first memory holds data of at least high-order two bits of the image data.

5. The memory apparatus according to claim 1, further comprising an error detection and correction unit that performs error detection and correction processing on the image data held in the second memory.

6. The memory apparatus according to claim 5, wherein the error detection and correction unit further performs error detection and generation processing on the image data held in the first memory.

7. An image sensor comprising:
an imaging element that generates image data;
a first memory that includes an SRAM and holds data of a high-order bit of the image data; and
a second memory that includes a memory having a cell area smaller than a cell area of the SRAM, the second memory holding data of a low-order bit of the image data.

8. The image sensor according to claim 7, further comprising:
a first semiconductor substrate on which an imaging element that generates the image data is arranged; and
a second semiconductor substrate on which the first memory and the second memory are arranged, the second semiconductor substrate being stacked on the first semiconductor substrate.

9. The image sensor according to claim 7, further comprising a semiconductor substrate on which the imaging element that generates the image data, the first memory, and the second memory are arranged.

10. An electronic apparatus comprising:
a memory apparatus including
a first memory that includes an SRAM and holds data of a high-order bit of image data, and
a second memory that includes a memory having a cell area smaller than a cell area of the SRAM, the second memory holding data of a low-order bit of the image data; and
a processing unit that performs processing of the image data.
